(19) United States
(12) Patent Application Publication
(10) Pub. No.: US 2024/0243213 A1
(43) Pub. Date: Jul. 18, 2024

(54) Single Photon Avalanche Diode

(71) Applicant: Seer Microelectronics, Inc., Hsinchu county (TW)

(72) Inventor: Ming-Ching Kuo, Hsinchu county (TW)

(21) Appl. No.: 18/510,712

(22) Filed: Nov. 16, 2023

Related U.S. Application Data
(60) Provisional application No. 63/383,988, filed on Nov. 16, 2022.

(51) Int. Cl. H01L 31/107

(52) U.S. Cl. CPC H01L 31/107

(57) ABSTRACT

The present application discloses a single photon avalanche diode, which comprises a first double diffusion region and a first heavily-doped implant region, the first double diffusion region is a second conductivity type. The first heavily-doped implant region is located on the first double diffusion region and is a first conductivity type, a multiplication region is formed between the first heavily-doped implant region and the first double diffusion region. The multiplication region of the single photon avalanche diode according to the present application is formed by the first double diffusion region, which may feature characteristics of low breakdown voltage and low dark count rate.

### FIELD OF THE INVENTION

The present application related to a photodiode, in particular to a single photon avalanche diode.

### BACKGROUND OF THE INVENTION

Photodiodes are applied for many applications in various fields of daily life. Among them, single-photon avalanche diodes (SPADs) have become increasingly widespread due to their high sensitivity, fast response, low power consumption, low noise, and high resolution. These advantages enable SPAD to be widely used in many emerging fields such as biomedicine, lidar, spectroscopy, and optical communications.

A single photon avalanche diode is a semiconductor device with the p-n junction operated at a reverse bias. The operating voltage of a single photon avalanche diode exceeds its breakdown voltage and is generally the breakdown voltage value plus an excess bias. Among the parameters to evaluate the performance of single photon avalanche diodes, one important parameter is the dark count rate (DCR), which refers to the number of breakdown events occurring within the device per unit time when no photons are incident on it. According to the prior art with a p+/n-well junction, the excessively high doping concentration of n-type well and p+ region leads to an extremely narrow depletion region. Consequently, a large number of tunneling-induced carriers contribute to the high dark count rate. Additionally, because the operating voltage of a single-photon avalanche diode must exceed its breakdown voltage, SPADs designed to reduce dark count rates often have elevated breakdown voltages, necessitating operation at high voltages.

To address these technical challenges, the present application provides a single-photon avalanche diode design. This design achieves the following advantages: lower operating voltage for the SPAD, increased maximum allowable excess bias voltage range, enhancing the photon detection probability (PDP) and maintaining low dark count rates, and reduced crosstalk.

### SUMMARY OF THE INVENTION

An objective of the present application is to provide a single photon avalanche diode, which uses a double diffusion region to form a multiplication region with a low breakdown voltage and a low dark count rate. In addition, the breakdown voltage has a low temperature coefficient.

An objective of the present application is to provide a single photon avalanche diode, which uses a double diffusion region to act as a guard ring for lowering the electric field at the corners of the structure and thus avoiding early breakdown on edges and failure of the single photon avalanche diode.

An objective of the present application is to provide a single photon avalanche diode, which may prevent the guard ring from electrical shortage and hence increasing the maximum allowable operating range of excess bias.

An objective of the present application is to provide a single photon avalanche diode, which uses a buried layer as an isolation layer for reducing crosstalk.

The present application provides a single photon avalanche diode, which comprises a first double diffusion region and a first heavily-doped implant region. The first heavily-doped implant region and the first double diffusion region are a first conductivity type and a second conductivity type, respectively. The first heavily-doped region is located on the first double diffusion region for forming a multiplication region therebetween. In addition, the single photon avalanche diode further comprises a guard ring region. The guard ring includes a second double diffusion region. The second double diffusion region is a first conductivity type and surrounds the first double diffusion region. Besides, the guard ring region may further include an epitaxial layer surrounding the second double diffusion region.

### BRIEF DESCRIPTION OF DRAWINGS

FIG. 1 shows a structural schematic diagram of the single photon avalanche diode according to an embodiment of the present application;

FIG. 2 shows a structural schematic diagram of the single photon avalanche diode according to another embodiment of the present application;

FIG. 3 shows a structural schematic diagram of the single photon avalanche diode according to another embodiment of the present application;

FIG. 4 shows a structural schematic diagram of the single photon avalanche diode according to another embodiment of the present application;

FIG. 5 shows a structural schematic diagram of the single photon avalanche diode according to another embodiment of FIG. 4 of the present application;

FIG. 6 shows a structural schematic diagram of the single photon avalanche diode according to another embodiment of the present application;

FIG. 7 shows a structural schematic diagram of the single photon avalanche diode according to another embodiment of FIG. 6 of the present application;

FIG. 8 shows a structural schematic diagram of the single photon avalanche diode according to another embodiment of the present application;

FIG. 9 shows a schematic diagram of the device of the single photon avalanche diode of the embodiment in FIG. 8 according to the present application;

FIG. 10 shows a structural schematic diagram of the single photon avalanche diode according to another embodiment of the present application; and

FIG. 11 shows a schematic diagram of the device of the single photon avalanche diode of the embodiment in FIG. 10 according to the present application.

### DETAILED DESCRIPTION OF THE INVENTION

In order to make the structure and characteristics as well as the effectiveness of the present application to be further understood and recognized, the detailed description of the present application is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

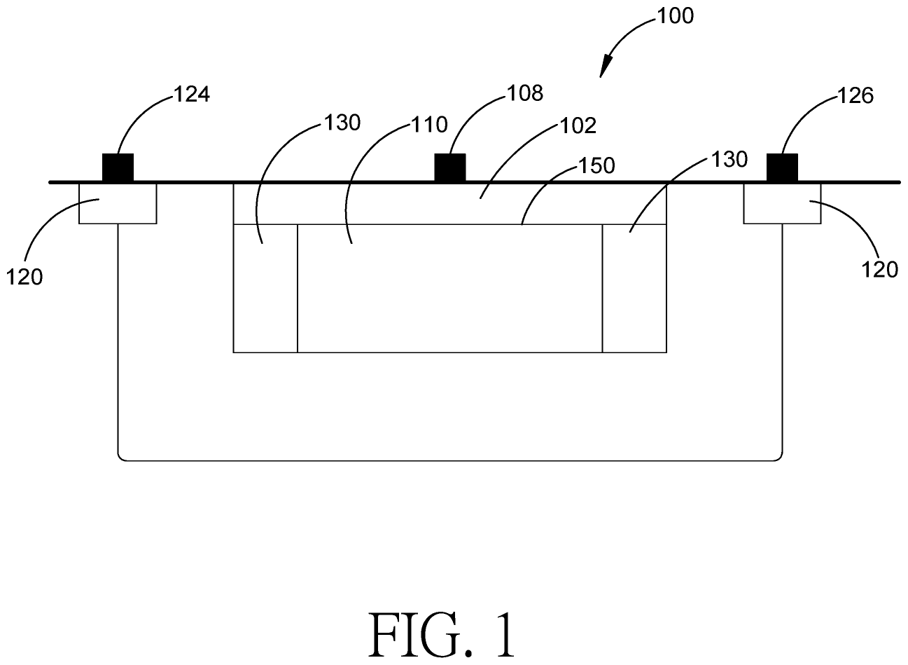

Please refer to FIG. 1, which shows a structural schematic diagram of the single photon avalanche diode according to an embodiment of the present application. The single photon avalanche diode 100 comprises a first heavily-doped implant region 102, a first double diffusion region 110, a second double diffusion region 130, a second heavily-doped implant region 120, a first electrode 108, second electrodes 124, 126. The second double diffusion region 130 surrounds the first double diffusion region 110 to form a guard ring region. The guard ring region formed by the second double diffusion region 130 may lower the electric field in the corner regions of the structure for preventing early breakdown on edges and failure of the single photon avalanche diode. The first heavily-doped implant region 102 is located on the first double diffusion region 110 and the second double diffusion region 130. When the first heavily-doped implant region 102 and the first double diffusion region 110 are applied by a bias voltage, the junction between the first heavily-doped implant region 102 and the first double diffusion region 110 forms a multiplication region 150 of the single photon avalanche diode. The first electrode 108 is disposed on the first heavily-doped implant region 102 and the second electrodes 124, 126 are disposed on the second heavily-doped implant region 120.

According to the present embodiment, the first electrode 108 is, for example, the cathode, and the second electrodes 124, 126 are, for example, the anodes. The first heavily-doped implant region 102 and the second double diffusion region 130 are the first conductivity type, which is, for example, the n-type. The first heavily-doped implant region 102 is a high-concentration n-type injection region. The second double diffusion region 130 is an n-type double diffusion region. The first double diffusion region 110 and the second heavily-doped implant region 120 are the second conductivity type, which is, for example, the p-type. The first double diffusion region 110 is a p-type double diffusion region. The second heavily-doped implant region 120 is a high-concentration p-type injection region.

According to another embodiment, the first conductivity type is, for example, the p-type, the second conductivity type is, for example, the n-type. The first heavily-doped implant region 102 is a high-concentration p-type injection region. The second double diffusion region 130 is a p-type double diffusion region. The first double diffusion region 110 is an n-type double diffusion region. The second heavily-doped implant region 120 is a high-concentration n-type injection region.

The structure of the first double diffusion region 110 is added into the design of the single photon avalanche diode according to the present application. By increasing the doping concentration at the junction between the first double diffusion region 110 and the first heavily-doped implant region 102, the single photon avalanche diode according to the present application may have a low breakdown voltage.

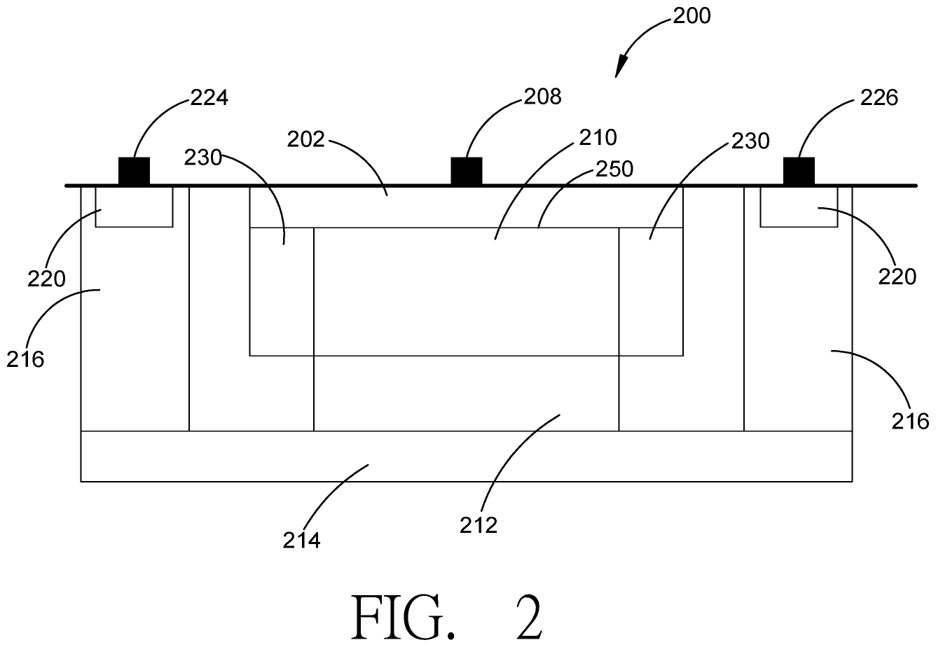

Please refer to FIG. 2, which shows a structural schematic diagram of the single photon avalanche diode according to another embodiment of the present application. The single photon avalanche diode 200 comprises a first heavily-doped implant region 202, a first double diffusion region 210, a second double diffusion region 230, a second heavily-doped implant region 220, a first electrode 208, second electrodes 224, 226, a second well 212, a deep well 214, and a first well 216. The second double diffusion region 230 surrounds the first double diffusion region 210 to form a guard ring region. The first heavily-doped implant region 202 is located on the first double diffusion region 210 and the second double diffusion region 230. The first heavily-doped implant region 202 and the first double diffusion region 210 form a multiplication region 250 therebetween. The first electrode 208 is disposed on the first heavily-doped implant region 202, and the second electrodes 224, 226 are disposed on the second heavily-doped implant region 220. The second well 212 and the first well 216 are formed on the deep well 214. The second heavily-doped implant region 220 is located on the first well 216. The first well 216 surrounds the second double diffusion region 230 and the first heavily-doped implant region 202. The second well 212 is coupled to the deep well 214 and the first double diffusion region 210. Thereby, the first double diffusion region 210 and the second double diffusion region 230 are located on the deep well 214. The second well 212 and the first heavily-doped implant region 202 are coupled each other, a breakdown voltage of approximately 30V at the junction between the second well 212 and the first heavily-doped implant region 202. The second well 212 is disposed on the first double diffusion region 210 for increasing the doping concentration at the junction between the second well 212 and the first double diffusion region 210, and thus lowering its breakdown voltage to, for example, 17˜19V. In addition, the breakdown voltage has a low temperature coefficient. It maintains the advantages of high photon detection probability and low dark count rate. By using the single photon avalanche diode, no high voltage is required, which simplifies the bias circuit and lowers the bill of materials.

According to the present embodiment, the first electrode 208 is, for example, the cathode, and the second electrodes 224, 226 are, for example, the anodes. The first heavily-doped implant region 202 and the second double diffusion region 230 are the first conductivity type, which is, for example, the n-type. The first double diffusion region 210, the second heavily-doped implant region 220, the second well 212, the deep well 214, and the first well 216 are the second conductivity type, which is, for example, the p-type. The second electrodes 224, 226 are coupled to the second heavily-doped implant region 220, which is the second conductivity type. The second heavily-doped implant region 220 is coupled to the first double diffusion region 210 through the conduction path formed by the first well 216, the deep well 214, and the second well 212 with the same conductivity type.

The single photon avalanche diode according to the present embodiment introduces the structure of the first double diffusion region 210 for increasing the doping concentration at the junction between the first double diffusion region 210 and the first heavily-doped implant region 202 and giving a lower breakdown voltage, for example, approximately 18V. In addition, the breakdown voltage has a low temperature coefficient. It maintains the advantages of high photon detection probability and low dark count rate.

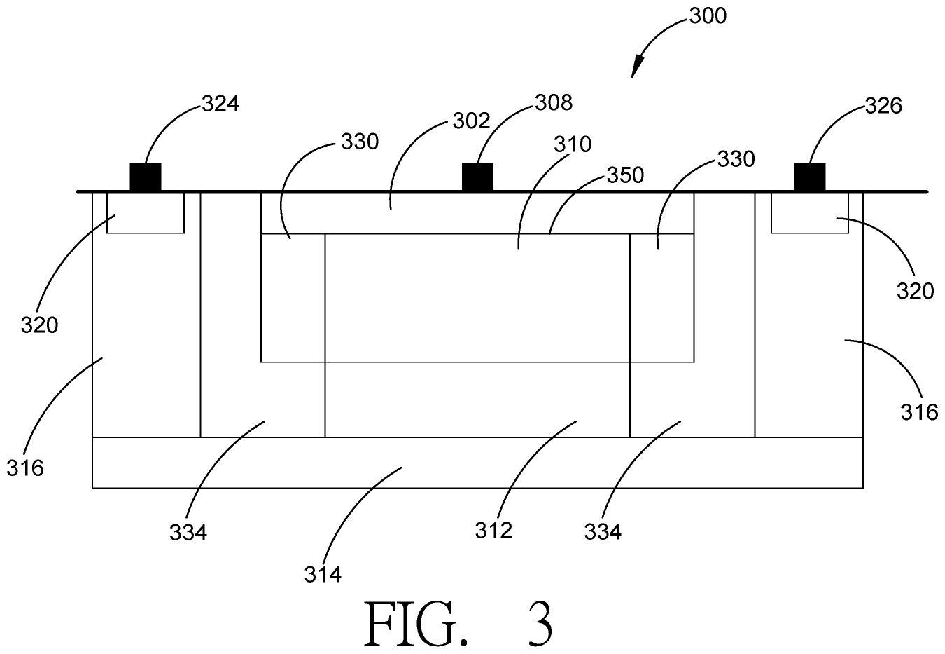

Please refer to FIG. 3, which shows a structural schematic diagram of the single photon avalanche diode according to another embodiment of the present application. The single photon avalanche diode 300 comprises a first heavily-doped implant region 302, a first double diffusion region 310, a second double diffusion region 330, a second heavily-doped implant region 320, a first electrode 308, second electrodes 324, 326, a second well 312, a deep well 314, a first well 316, and an epitaxial layer 334. The second double diffusion region 330 surrounds the first double diffusion region 310 to form a guard ring region. The guard ring region formed by the second double diffusion region 330 further includes the epitaxial layer 334 located between the second double diffusion region 330 and the first well 316. The epitaxial layer 334 is located on the deep well 314 and surrounds the second double diffusion region 330. According to an embodiment, the epitaxial layer 334 is a p-type epitaxy (P-epi) without any shallow doping. According to another embodiment, the epitaxial layer 334 may be a substrate layer (P-sub) without any shallow doping. The second well 312 and the first well 316 are formed on the deep well 314. The first well 316 surrounds the epitaxial layer 334. The epitaxial layer 334 surrounds the second well 312 and located between the first well 316 and the second well 312. The second well 312 is coupled to the deep well 314 and the first double diffusion region 310. Thereby, the first double diffusion region 310 and the second double diffusion region 330 are located on the deep well 314. The first heavily-doped implant region 302 is located on the first double diffusion region 310 and the second double diffusion region 330. The first heavily-doped implant region 302 and the first double diffusion region 310 form a multiplication region 350 therebetween. The first electrode 308 is disposed on the first heavily-doped implant region 302 and the second electrodes 324, 326 are disposed on the second heavily-doped implant region 320.

According to the present embodiment, the first electrode 308 is, for example, the cathode, and the second electrodes 324, 326 are, for example, the anodes. The first heavily-doped implant region 302 and the second double diffusion region 330 are the first conductivity type, which is, for example, the n-type. The first double diffusion region 310, the second heavily-doped implant region 320, the second well 312, the deep well 314, and the first well 316 are the second conductivity type, which is, for example, the p-type. The second heavily-doped implant region 320 is coupled to the first double diffusion region 310 through the conduction path formed by the first well 316, the deep well 314, and the second well 312 with the same conductivity type.

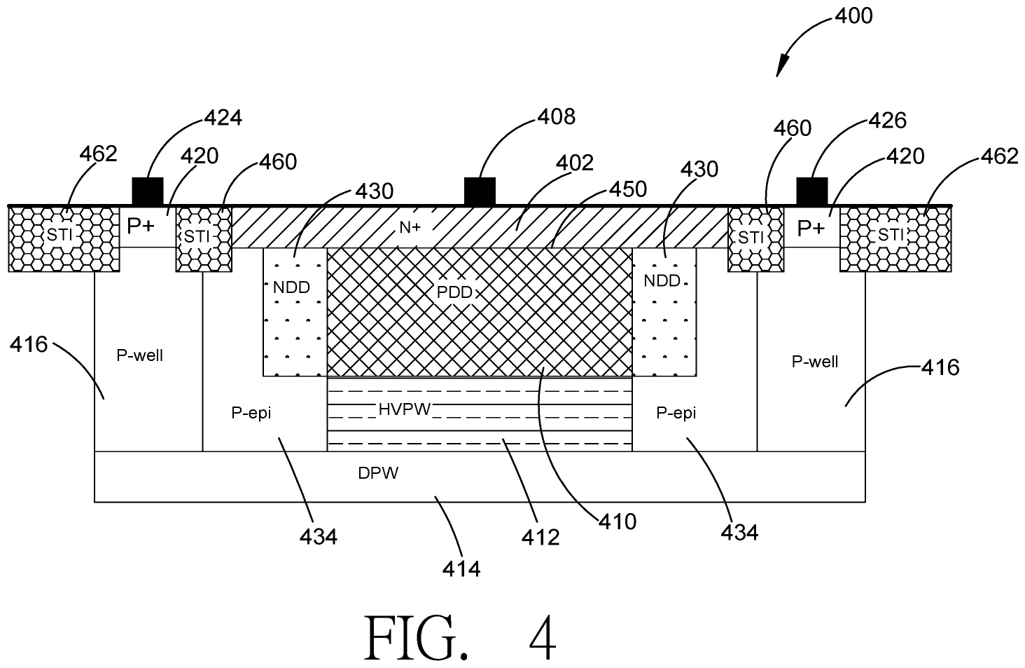

Please refer to FIG. 4, which shows a structural schematic diagram of the single photon avalanche diode according to another embodiment of the present application. The single photon avalanche diode 400 comprises a first heavily-doped implant region 402, a first double diffusion region 410, a second double diffusion region 430, a second heavily-doped implant region 420, a first electrode 408, second electrodes 424, 426, a second well 412, a deep well 414, a first well 416, an epitaxial layer 434, and shallow trench isolation (STI) layers 460, 462. The second double diffusion region 430 surrounds the first double diffusion region 410 to form a guard ring region. The first heavily-doped implant region 402 is located on the first double diffusion region 410 and the second double diffusion region 430. The first heavily-doped implant region 402 and the first double diffusion region 410 form a multiplication region 450 therebetween. The first electrode 408 is disposed on the first heavily-doped implant region 402, and the second electrodes 424, 426 are disposed on the second heavily-doped implant region 420. The first electrode 408 according to the present embodiment is disposed on the first heavily-doped implant region 402 approximately at the center of the multiplication region 450 so that the electric field at the center may be more uniform. The second well 412 and the first well 416 are formed on the deep well 414. The epitaxial layer 434 is located on the deep well 414 and surrounds the second double diffusion region 430. The shallow trench isolation layers 460, 462 are respectively disposed between the heavily-doped implant regions 402, 420 to isolate the heavily-doped implant regions 402, 420.

According to the present embodiment, the first electrode 408 is, for example, the cathode, and the second electrodes 424, 426 are, for example, the anodes. The first heavily-doped implant region 402 and the second double diffusion region 430 are the first conductivity type, which is, for example, the n-type. The first heavily-doped implant region 402 is a high-concentration n-type injection region (N+). The second double diffusion region 430 is an n-type double diffusion region (NDD). The first double diffusion region 410, the second heavily-doped implant region 420, the second well 412, the deep well 414, and the first well 416 are the second conductivity type, which is, for example, the p-type. The first double diffusion region 410 is a p-type double diffusion region (PDD). The second heavily-doped implant region 420 is a high-concentration p-type injection layer (P+). The second well 412 is a high-voltage p-type well (HVPW). The deep well 414 is a deep p-type well (DPW). The first well 416 is a p-type well (P-well). The epitaxial layer 434 is a p-type epitaxy (P-epi) without any shallow doping. According to another embodiment, the epitaxial layer 434 may be a substrate layer (P-sub) without any shallow doping. The second heavily-doped implant region 420 is coupled to the first double diffusion region 410 through the conduction path formed by the first well 416, the deep well 414, and the second well 412 with the same conductivity type.

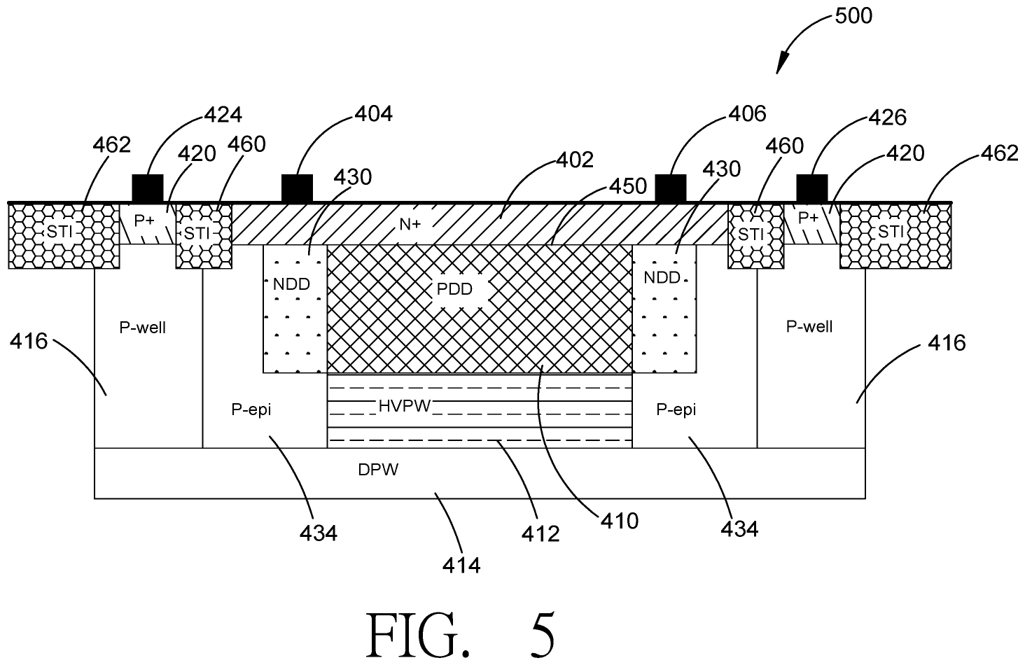

Please refer to FIG. 5, which shows a structural schematic diagram of the single photon avalanche diode according to another embodiment of FIG. 4 of the present application. The difference between the present embodiment and the embodiment in FIG. 4 is the disposition of the first electrode 408. The other elements having the same disposition will not be described again here. The first electrode according to the present embodiment is disposed on the periphery of the first heavily-doped implant region 402, for example, in a ring shape or in multiple points. In other words, the first electrode is not located at the center of the multiplication region 450. For example, it may be the first electrodes 404, 406 shown in the figure. The contact of the electrode is designed at the periphery of the device to prevent metal interconnect from sheltering the active sensing area, hence maximizing the photon detection efficiency.

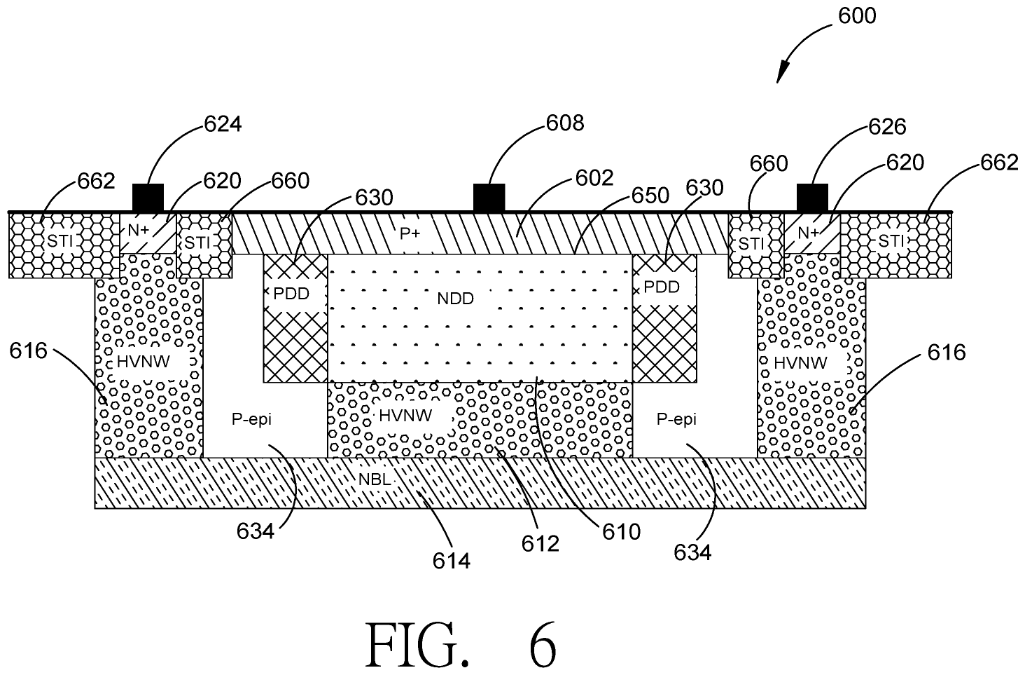

Please refer to FIG. 6, which shows a structural schematic diagram of the single photon avalanche diode according to another embodiment of the present application. The single photon avalanche diode 600 comprises a first heavily-doped implant region 602, a first double diffusion region 610, a second double diffusion region 630, a second heavily-doped implant region 620, a first electrode 608, second electrodes 624, 626, a second well 612, a deep well 614, a first well 616, an epitaxial layer 634, and shallow trench isolation layers 660, 662. The second double diffusion region 630 surrounds the first double diffusion region 610 to form a guard ring region. The first heavily-doped implant region 602 is located on the first double diffusion region 610 and the second double diffusion region 630. The first heavily-doped implant region 602 and the first double diffusion region 610 form a multiplication region 650 therebetween. The first electrode 608 is disposed on the first heavily-doped implant region 602 and the second electrodes 624, 626 are disposed on the second heavily-doped implant region 620. The shallow trench isolation layers 660, 662 are respectively disposed between the heavily-doped implant regions 602, 620 to isolate the heavily-doped implant regions 602, 620. The first electrode 608 according to the present embodiment is disposed on the first heavily-doped implant region 602 approximately at the center of the multiplication region 650 so that the electric field at the center may be more uniform.

According to the present embodiment, the first electrode 608 is, for example, the anode, and the second electrodes 624, 626 are, for example, the cathodes. The first heavily-doped implant region 602 and the second double diffusion region 630 are the first conductivity type, which is, for example, the p-type. The first heavily-doped implant region 602 is a high-concentration p-type injection region (P+). The second double diffusion region 630 is a p-type double diffusion region (PDD). The first double diffusion region 610, the second heavily-doped implant region 620, the second well 612, the deep well 614, and the first well 616 are the second conductivity type, which is, for example, the n-type. The first double diffusion region 610 is an n-type double diffusion region (NDD). The second heavily-doped implant region 620 is a high-concentration n-type injection layer (N+). The second well 612 is a high-voltage n-type well (HVNW). The deep well 614 is an n-type buried layer (N+ buried layer, NBL). The first well 616 is a high-voltage n-type well (HVNW). The epitaxial layer 634 is a p-type epitaxy (P-epi) without any shallow doping. According to another embodiment, the epitaxial layer 634 may be a substrate layer (P-sub) without any shallow doping. The second heavily-doped implant region 620 is coupled to the first double diffusion region 610 through the conduction path formed by the first well 616, the deep well 614, and the second well 612 with the same conductivity type.

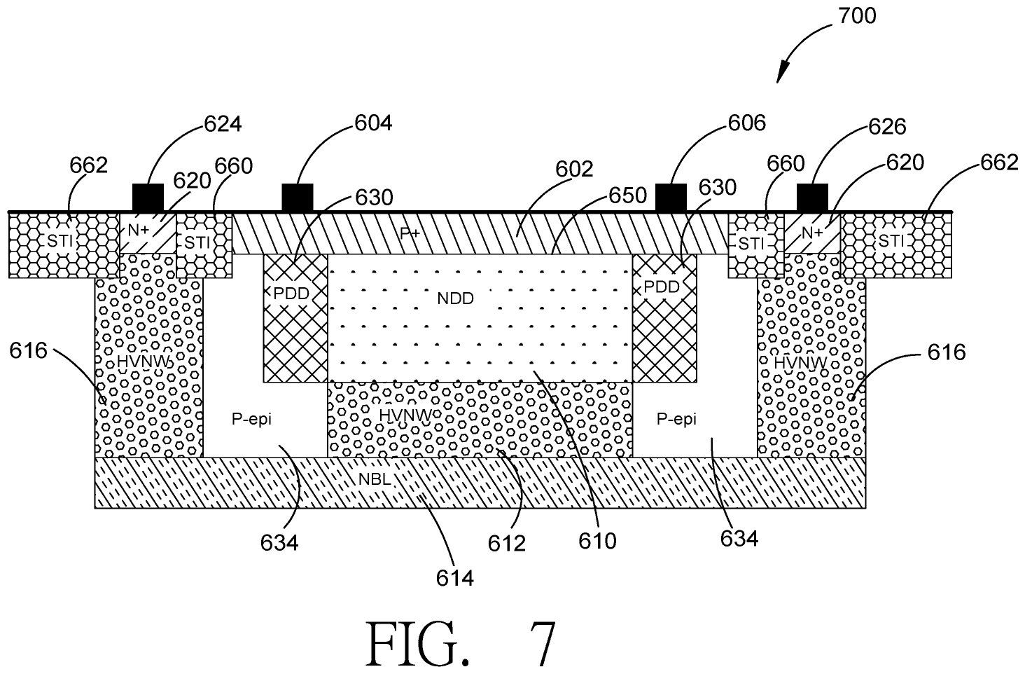

Please refer to FIG. 7, which shows a structural schematic diagram of the single photon avalanche diode according to another embodiment of FIG. 6 of the present application. The difference between the present embodiment and the embodiment in FIG. 6 is the disposition of the first electrode. The other elements having the same disposition will not be described again here. The first electrode according to the present embodiment is disposed on the periphery of the first heavily-doped implant region 602, for example, in a ring shape or in multiple points. In other words, the first electrode is not located at the center of the multiplication region 650. For example, it may be the first electrodes 604, 606 shown in the figure. The contact of the electrode is designed at the periphery of the device to prevent metal interconnect from sheltering the active sensing area, hence maximizing the photon detection efficiency.

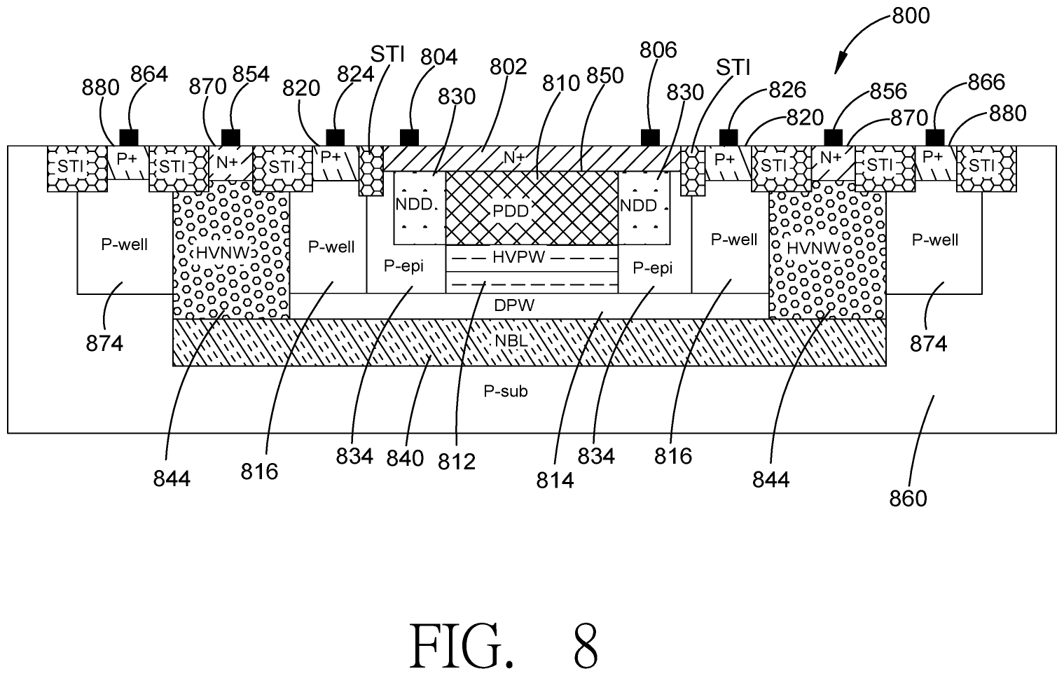

Please refer to FIG. 8, which shows a structural schematic diagram of the single photon avalanche diode according to another embodiment of the present application. The single photon avalanche diode 800 comprises a first heavily-doped implant region 802, a first double diffusion region 810, a second double diffusion region 830, a second heavily-doped implant region 820, a third heavily-doped implant region 870, a fourth heavily-doped implant region 880, first electrodes 804, 806, second electrodes 824, 826, third electrodes 854, 856, fourth electrodes 864, 866, a second well 812, a deep well 814, a first well 816, a well 844, a buried layer 840, an epitaxial layer 834, a substrate layer 860, a well 874, and shallow trench isolation layers STI. The second double diffusion region 830 surrounds the first double diffusion region 810 to form a guard ring region. The first heavily-doped implant region 802 is located on the first double diffusion region 810 and the second double diffusion region 830. The first heavily-doped implant region 802 and the first double diffusion region 810 form a multiplication region 850 therebetween. The first electrodes 804, 806 are disposed on the first heavily-doped implant region 802, and the second electrodes 824, 826 are disposed on the second heavily-doped implant region 820. The third electrodes 854, 856 are disposed on the third heavily-doped implant region 870. The fourth electrodes 864, 866 are disposed on the fourth heavily-doped implant region 880. The buried layer 840 is located between the substrate layer 860 and the deep well 814. The well 844 is located on the buried layer 840 and surrounds the first well 816. The well 874 is located on the substrate layer 860. The third heavily-doped implant region 870 is located on the well 844. The fourth heavily-doped implant region 880 is located on the well 874.

According to the present embodiment, the first electrodes 804, 806 are, for example, the cathodes, the second electrodes 824, 826 are, for example, the anodes, the third electrodes 854, 856 are, for example, the isolation electrodes, and the fourth electrodes 864, 866 are, for example, the body electrodes. The first heavily-doped implant region 802, the second double diffusion region 830, the well 844, the buried layer 840, and the third heavily-doped implant region 870 are the first conductivity type, which is, for example, the n-type. The first heavily-doped implant region 802 is a high-concentration n-type injection region (N+). The second double diffusion region 830 is an n-type double diffusion region (NDD). The well 844 is a high-voltage n-type well (HVNW). The buried layer 840 is an n-type buried layer (NBL). The third heavily-doped layer 870 is a high-concentration n-type injection region (N+). The first double diffusion region 810, the second heavily-doped implant region 820, the second well 812, the deep well 814, the first well 816, the well 874, and the fourth heavily-doped implant region 880 are the second conductivity type, which is, for example, the p-type. The first double diffusion region 810 is a p-type double diffusion region (PDD). The second heavily-doped implant region 820 is a high-concentration p-type injection layer (P+). The second well 812 is a high-voltage p-type well (HVPW). The deep well 814 is a deep p-type well (DPW). The first well 816 is a p-type well (P-well). The well 874 is a p-type well (P-well). The fourth heavily-doped implant region 880 is a high-concentration p-type injection region (P+). The substrate layer 860 is a p-type doping layer (P-sub). The epitaxial layer 834 is a p-type epitaxy (P-epi) without any shallow doping. According to another embodiment, the epitaxial layer 834 may be a substrate layer (P-sub) without any shallow doping. The second heavily-doped implant region 820 is coupled to the first double diffusion region 810 through the conduction path formed by the first well 816, the deep well 814, and the second well 812 with the same conductivity type. The third heavily-doped implant region 870 is coupled to the buried layer 840 through the conduction path formed by the well 844 with the same conductivity type. By using the buried layer 840, the device and the substrate layer 860 may be isolated for preventing crosstalk effect. The fourth heavily-doped implant region 880 is coupled to the substrate layer 860 through the conduction path formed by the well 874 with the same conductivity type. The shallow trench isolation layers STI are respectively disposed between the heavily-doped implant regions to isolate each of the heavily-doped implant regions.

According to the present embodiment, by introducing the deep well 814, the electrical shortage between structures may be avoided. For example, the deep well 814 may further isolate the second double diffusion region 830 and the buried layer 840 for preventing electrical short therebetween at high operating voltage. The electrical short may lead to the device performance degradation or failure. This design may increase the maximum allowable operating range of excess bias, improve the photon detection probability, ensure a low dark count rate, and reduce crosstalk.

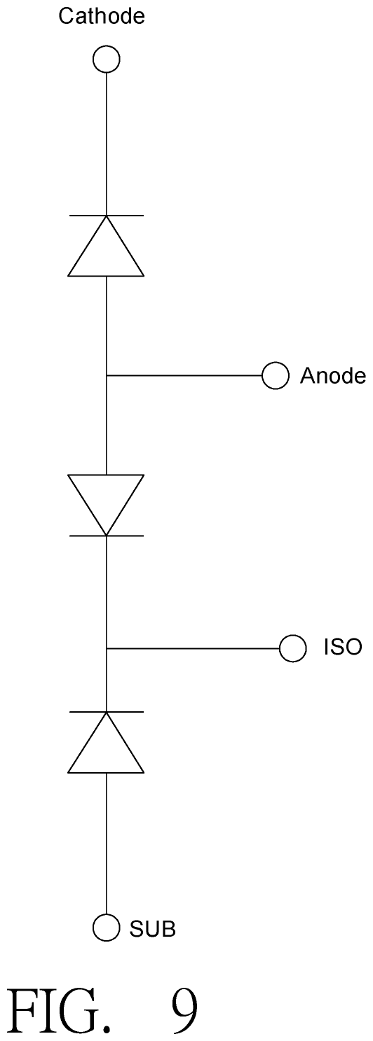

Please refer to FIG. 9, which shows a schematic diagram of the device of the single photon avalanche diode of the embodiment in FIG. 8 according to the present application. The single photon avalanche diode according to the present embodiment comprises a first terminal Cathode (the first electrode), a second terminal Anode (the second electrode), a third terminal ISO (the third electrode), and a fourth terminal SUB (the fourth electrode). The third terminal ISO represents the isolation pin of the device. The design of the buried layer in the single photon avalanche diode according to the present application enables effective isolation between the device and the substrate. When the application of single photon avalanche diode is extended to an array, this isolation design may prevent the problem of crosstalk effectively. The junction of the main multiplication region of the present device is located between the first terminal Cathode and the second terminal Anode with a low breakdown voltage, for example, 18V, which is much lower than the other two parasitic diodes. For example, the parasitic diode between the second terminal Anode and the third terminal ISO has a breakdown voltage of about 50V, the parasitic diode between the third terminal ISO and the fourth terminal SUB has a breakdown voltage of about 70V. When applied a proper operating bias to the single photon avalanche diode, under which bias the parasitic diodes are not conducted, the operation characteristics of the single photon avalanche diode will not be affected.

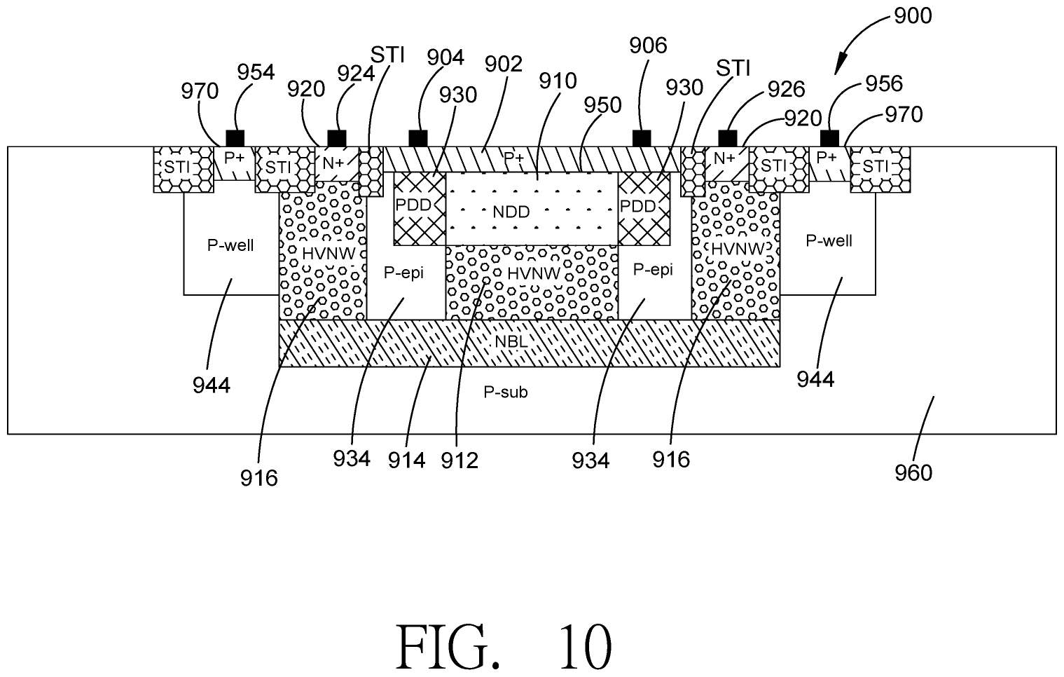

Please refer to FIG. 10, which shows a structural schematic diagram of the single photon avalanche diode according to another embodiment of the present application. The single photon avalanche diode 900 comprises a first heavily-doped implant region 902, a first double diffusion region 910, a second double diffusion region 930, a second heavily-doped implant region 920, first electrode 904, 906, second electrodes 924, 926, third electrodes 954, 956, a second well 912, a well 914, a first well 916, a well 944, an epitaxial layer 934, a substrate layer 960, a third heavily-doped implant region 970, and shallow trench isolation layers STI. The second double diffusion region 930 surrounds the first double diffusion region 910 to form a guard ring region. The first heavily-doped implant region 902 is located on the first double diffusion region 910 and the second double diffusion region 930. The first heavily-doped implant region 902 and the first double diffusion region 910 form a multiplication region 950 therebetween. The first electrodes 904, 906 are disposed on the first heavily-doped implant region 902 and the second electrodes 924, 926 are disposed on the second heavily-doped implant region 920. The third electrodes 954, 956 are disposed on the third heavily-doped implant region 970. The well 914 is located between the substrate layer 960 and the second well 912. The well 944 is located on the substrate layer 960. The third heavily-doped implant region 970 is located on the well 944. The well 914 may be a deep well or a buried layer.

According to the present embodiment, the first electrodes 904, 906 are, for example, the anodes, the second electrodes 924, 926 are, for example, the cathodes, and the third electrodes 954, 956 are, for example, the substrate electrodes. The first heavily-doped implant region 902, the second double diffusion region 930, the well 944, and the third heavily-doped implant region 970 are the first conductivity type, which is, for example, the p-type. The first heavily-doped implant region 902 is a high-concentration p-type injection region (P+). The second double diffusion region 930 is a p-type double diffusion region (PDD). The well 944 is a p-type well (P-well). The third heavily-doped layer 970 is a high-concentration p-type injection region (P+). The substrate layer 960 is a p-type doping layer (P-sub). The epitaxial layer 934 is a p-type epitaxy (P-epi) without any shallow doping. According to another embodiment, the epitaxial layer 934 may be a substrate layer (P-sub) without any shallow doping. The first double diffusion region 910, the second heavily-doped implant region 920, the second well 912, the well 914, and the first well 916 are the second conductivity type, which is, for example, the n-type. The first double diffusion region 910 is an n-type double diffusion region (NDD). The second heavily-doped implant region 920 is a high-concentration n-type injection layer (N+). The second well 912 is a high-voltage n-type well (HVNW). The well 914 is an n-type buried layer (NBL). The first well 916 is a high-voltage n-type well (HVNW). The second heavily-doped implant region 920 is coupled to the first double diffusion region 910 through the conduction path formed by the first well 916, the well 914, and the second well 912 with the same conductivity type. The third heavily-doped implant region 970 is coupled to the substrate layer 960 through the conduction path formed by the well 944 with the same conductivity type. The shallow trench isolation layers STI are respectively disposed between the heavily-doped implant regions to isolate each of the heavily-doped implant regions.

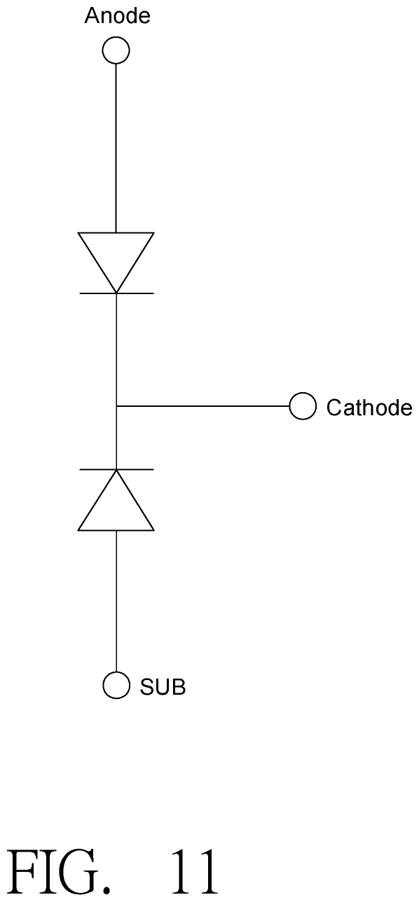

Please refer to FIG. 11, which shows a schematic diagram of the single photon avalanche diode of the embodiment in FIG. 10 according to the present application. The single photon avalanche diode according to the present embodiment comprises a first terminal Anode (the first electrode), a second terminal Cathode (the second electrode), and a third terminal SUB (the third electrode). The junction of the main multiplication region of the device is located between the first terminal Anode and the second terminal Cathode with a low breakdown voltage, which is much lower than the parasitic diode below. The parasitic diode between the second terminal Cathode and the third terminal SUB has a breakdown voltage of about 70V.

Accordingly, the present application conforms to the legal requirements owing to its novelty, nonobviousness, and utility. However, the foregoing description is only embodiments of the present application, not used to limit the scope and range of the present application. Those equivalent changes or modifications made according to the shape, structure, feature, or spirit described in the claims of the present application are included in the appended claims of the present application.

1. A single photon avalanche diode, comprising:
a first double diffusion region, being a second conductivity type; and
a first heavily-doped implant region, located on said first double diffusion region, being a first conductivity type, and a multiplication region formed between said first heavily-doped implant region and said first double diffusion region.

2. The single photon avalanche diode of claim 1, further comprising:
a guard ring, comprising a second double diffusion region, said second double diffusion region being said first conductivity type and surrounding said first double diffusion region.

3. The single photon avalanche diode of claim 2, wherein said guard ring further comprises an epitaxial layer surrounding said second double diffusion region.

4. The single photon avalanche diode of claim 2, wherein said guard ring further comprises a substrate layer surrounding said second double diffusion region.

5. The single photon avalanche diode of claim 3, further comprising:
a deep well, being said second conductivity type, and said second double diffusion region and said epitaxial layer located on said deep well.

6. The single photon avalanche diode of claim 5, further comprising:
a first well, being said second conductivity type, located on said deep well, and surrounding said epitaxial layer; and
a second well, being said second conductivity type, and located between said deep well and said first double diffusion region, said epitaxial layer surrounding said second well, and located between said first well and said second well.

7. The single photon avalanche diode of claim 6, further comprising:
a second heavily-doped implant region, being said second conductivity type, and located on said first well;
a first electrode, disposed on said first heavily-doped implant region; and
a second electrode, disposed on said second heavily-doped implant region.

8. The single photon avalanche diode of claim 7, further comprising:
a shallow trench isolation layer, surrounding said first heavily-doped implant region, and located between said first heavily-doped implant region and said second heavily-doped implant region.

9. The single photon avalanche diode of claim 3, further comprising:
a buried layer, being said second conductivity type, and said second double diffusion region and said epitaxial layer located on said buried layer.

10. The single photon avalanche diode of claim 9, further comprising:
a first well, being said second conductivity type, located on said buried layer, and surrounding said epitaxial layer; and
a second well, being said second conductivity type, and located between said buried layer and said first double diffusion region, said epitaxial layer surrounding said second well, and located between said first well and said second well.

11. The single photon avalanche diode of claim 10, further comprising:
a second heavily-doped implant region, being said second conductivity type, and located on said first well;
a first electrode, disposed on said first heavily-doped implant region; and
a second electrode, disposed on said second heavily-doped implant region.
